(19) United States
(12) Patent Application Publication
(10) Pub. No.: US 2015/0262690 A1
(43) Pub. Date: Sep. 17, 2015

(54) SEMICONDUCTOR MEMORY DEVICE

(71) Applicant: KABUSHIKI KAISHA TOSHIBA, Tokyo (JP)

(72) Inventor: Takashi MAEDA, Yokohama Kanagawa (JP)

(21) Appl. No.: 14/470,789

(22) Filed: Aug. 27, 2014

(30) Foreign Application Priority Data
Mar. 14, 2014 (JP) 2014-052782

(51) Int. Cl. G11C 16/26; G11C 16/24; G11C 16/04

(52) U.S. Cl. CPC G11C 16/26; G11C 16/0483; G11C 16/24

(57) ABSTRACT

A semiconductor memory device includes a memory cell, a bit line that is electrically connected to the memory cell, a sense module that includes a first transistor, a sense node electrically connected to the bit line through the first transistor, a second transistor electrically connected between a power source voltage and the sense node, a voltage generating circuit capable of generating a voltage that is equal to the first voltage minus a threshold voltage of the second transistor, and a control circuit configured to turn on the first transistor for a period of time prior to performing a sense operation on the bit line through the sense module.

### CROSS-REFERENCE TO RELATED APPLICATION

This application is based upon and claims the benefit of priority from Japanese Patent Application No. 2014-052782, filed Mar. 14, 2014, the entire contents of which are incorporated herein by reference.

### FIELD

Embodiments described herein relate generally to a semiconductor memory device.

### BACKGROUND

A technique that senses data retained in a memory cell using a sense amplifier during a data read operation or a verify operation in a NAND flash memory is proposed.

### DESCRIPTION OF THE DRAWINGS

FIG. 1 is a block diagram schematically illustrating a basic configuration of a semiconductor memory device according to a first embodiment.

FIG. 2 is a block diagram schematically illustrating a basic configuration of a bit line control circuit according to the first embodiment.

FIG. 3 is a circuit diagram schematically illustrating a basic configuration of a sense module according to the first embodiment.

FIG. 4 is a circuit diagram illustrating a basic configuration of a CLK generating circuit according to the first embodiment.

FIG. 5 is a timing chart illustrating a sense operation of the sense module according to the first embodiment.

FIG. 6 is a block diagram illustrating a sense operation of the sense module according to the first embodiment.

FIG. 7 is a block diagram illustrating a sense operation of a sense module according to a comparative example.

FIG. 8 is a graph illustrating an electric potential change of a sense node in the sense operation of the sense module according to the comparative example.

FIG. 9 is a graph illustrating an electric potential change of a sense node in a negative sense operation of the sense module according to the comparative example.

FIG. 10 is a circuit diagram schematically illustrating a configuration of an accelerator according to the first embodiment.

FIG. 11 is a timing chart illustrating a sense operation of a sense module according to a second embodiment.

FIG. 12 is a circuit diagram illustrating a basic configuration of a sense module according to a third embodiment.

FIG. 13 is a timing chart illustrating a sense operation of the sense module according to the third embodiment.

FIG. 14 is a block diagram illustrating the sense operation of the sense module according to the third embodiment.

FIG. 15 is a circuit diagram illustrating a basic configuration of a CLK generating circuit according to a fourth embodiment.

### DETAILED DESCRIPTION

The present embodiments now will be described more fully hereinafter with reference to the accompanying drawings, in which various embodiments are shown. In the drawings, the thickness of layers and regions may be exaggerated for clarity. Like numbers refer to like elements throughout. As used herein, the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it can be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it can be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, can therefore, encompass both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross sections and perspective illustrations that are schematic illustrations of embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

An advantage of some aspects of an exemplary embodiment is to provide a semiconductor memory device of high quality.

In general, according to one embodiment, a semiconductor memory device includes a memory cell, a bit line that is electrically connected to the memory cell, a sense module that includes a first transistor, a sense node electrically connected to the bit line through the first transistor, a second transistor electrically connected between a power source voltage and the sense node, a voltage generating circuit capable of generating a voltage that is equal to the first voltage minus a threshold voltage of the second transistor, and a control circuit configured to turn on the first transistor for a period of time prior to performing a sense operation on the bit line through the sense module.

### First Embodiment

Overall Configuration of Semiconductor Memory Device

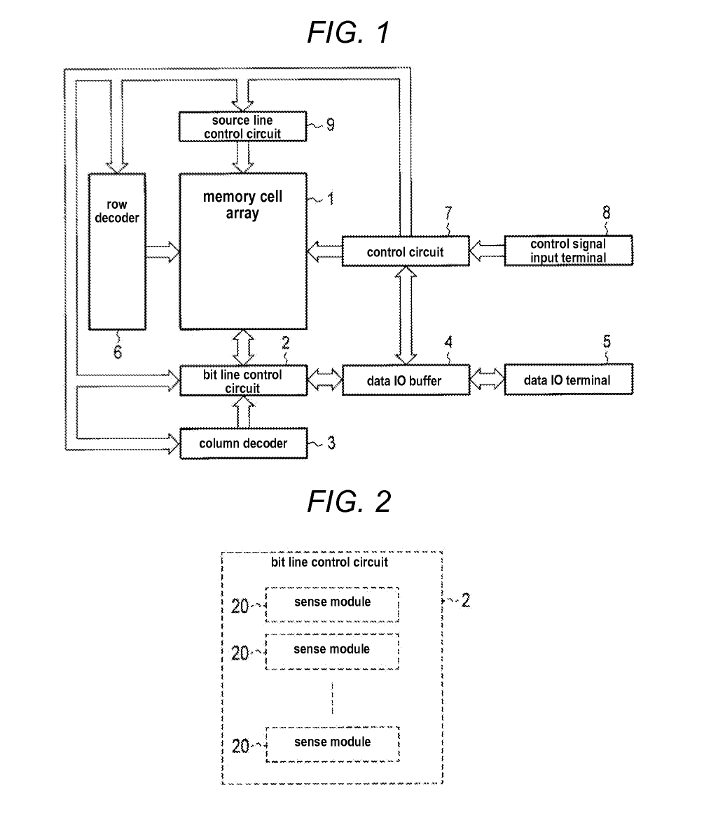

A configuration of a semiconductor memory device according to a first embodiment will be briefly described with reference to FIGS. 1 and 2.

As shown in FIG. 1, a semiconductor memory device 100 includes a memory cell array 1, a bit line control circuit 2, a column decoder 3, a data input/output buffer 4, a data input/output terminal 5, a row decoder 6, a control circuit 7, a control signal input terminal 8, and a source line control circuit 9. In this disclosure, the semiconductor memory device 100 will be described as a NAND flash memory.

The memory cell array 1 includes plural bit lines BL, plural word lines WL, and a source line SRC. The memory cell array 1 is configured with plural blocks BLK in which electrically rewritable memory cells MC are arranged in a matrix form. Each memory cell MC has a stacked structure including a control gate electrode and a floating gate electrode, and stores binary or multinary data according to a change of a threshold value of a transistor determined by the amount of charges injected into the floating gate electrode. Further, the memory cell MC may have a metal-oxide-nitride-oxide-silicon (MONOS) structure in which electrons are trapped in a nitride film. Furthermore, the memory cell array 1 may be a nonvolatile semiconductor memory device of a three-dimensional stacked type in which plural memory cells are stacked in a direction perpendicular to a substrate.

The bit line control circuit 2 that controls a voltage of the bit lines BL and the row decoder 6 that controls a voltage of the word lines WL are connected to the memory cell array 1. In a data erase operation, a certain block BLK is selected by the row decoder 6, and the other blocks BLK are not selected.

As shown in FIG. 2, the bit line control circuit 2 includes plural sense modules 20 for each bit line BL. The bit line control circuit 2 reads data of the memory cells MC of the memory cell array 1 through the bit lines BL, detects the states of the memory cells MC through the bit lines BL, or writes data of the memory cells MC by applying a write control voltage to the memory cells MC through the bit lines BL.

As shown in FIG. 1, the column decoder 3 and the data input/output buffer 4 are connected to the bit line control circuit 2. A data storage circuit in the bit line control circuit 2 is selected by the column decoder 3, and the data of the memory cells MC that is read into the data storage circuit is output to the outside from the data input/output terminal 5 through the data input/output buffer 4.

Further, write data that is input from the outside through the data input/output terminal 5 and through the data input/output buffer 4 is stored in the data storage circuit selected by the column decoder 3. Various commands such as writing, reading, erasing and status reading, and addresses, in addition to the write data, are also input through the data input/output terminal 5.

The row decoder 6 is connected to the memory cell array 1. The row decoder 6 applies a voltage necessary for a read operation, a write operation or an erase operation to the word lines WL and a selected gate line of the memory cell array 1.

The source line control circuit 9 is connected to the memory cell array 1. The source line control circuit 9 controls a voltage of the source line SRC.

The control circuit 7 controls the memory cell array 1, the bit line control circuit 2, the column decoder 3, the data input/output buffer 4, the row decoder 6, and the source line control circuit 9. It is assumed that a boosting circuit (not shown) that boosts a power source voltage is included in the control circuit 7. The control circuit 7 boosts the power source voltage using the boosting circuit as necessary, and supplies the boosted voltage to the bit line control circuit 2, the column decoder 3, the data input/output buffer 4, the row decoder 6, and the source line control circuit 9.

The control circuit 7 performs a control operation according to a control signal (a command latch enable signal CLE, an address latch enable signal ALE, a ready/busy signal RY/BY, or the like) that is input from the outside through the control signal input terminal 8 and a command that is input from the data input/output terminal 5 through the data input/output buffer 4. That is, the control circuit 7 generates a desired voltage when programming, verifying, reading or erasing data according to the control signal and the command, and supplies the generated voltage to the respective components of the memory cell array 1.

Here, for example, the memory cell array 1 includes the blocks BLK (BLK0, BLK1, . . . and BLKn (n is an arbitrary integer of 0 or more)) that include plural NAND strings 10 formed of the plural memory cells MC that are serially connected, for example. The NAND string 10 is formed of m (for example, 64) memory cells MC that are serially connected. A drain side select MOS transistor SGD is connected to one end of the NAND string 10, and a source side select MOS transistor SGS is connected to the other end thereof. Further, the drain side select MOS transistor SGD is connected to the bit line BL. Further, the source side select MOS transistor SGS is connected to the source line SRC.

The control gate electrodes of the memory cells MC arranged in each row are respectively connected to the word lines WL0 to WLn. A gate of the drain side select MOS transistor SGD is connected to a drain side select gate line VSGD. Agate of the source side select MOS transistor SGS is connected to a source side select gate line VSGS.

That is, the row decoder 6 selects an arbitrary block BLK in the memory cell array 1, and executes a write operation or a read operation for the selected block BLK.

On the other hand, the bit lines BL0, BL1, and BL2 are extended in a direction perpendicular to the word lines WL0 to WLn.

A sense module 20 of the bit line control circuit 2 senses or controls an electric potential of the connected bit line BL.

Configuration of Sense Module

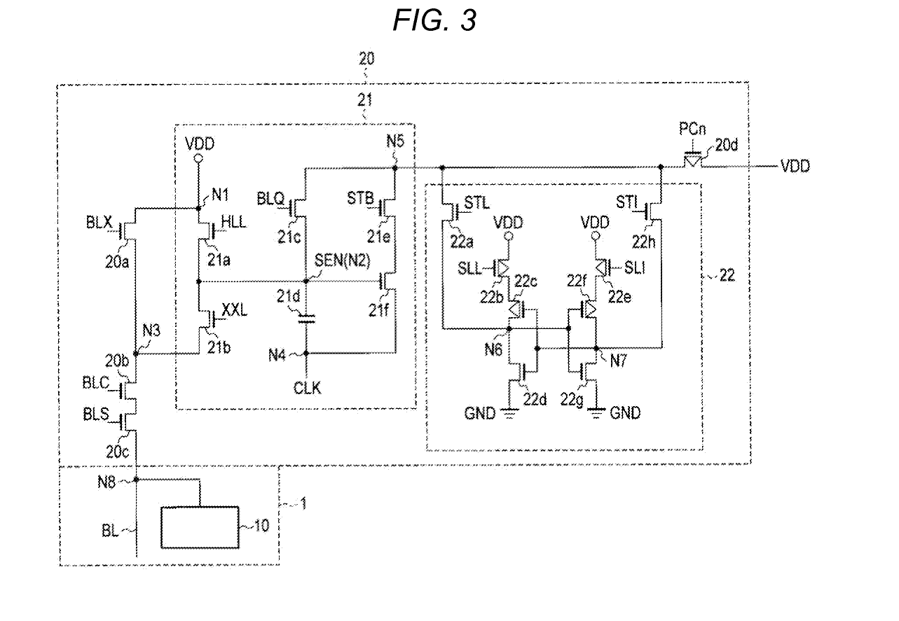

Next, a basic configuration of the sense module 20 according to the present embodiment will be briefly described with reference to FIG. 3.

The sense module 20 includes a sense amplifier (S/A) 21 that senses and amplifies a voltage of the bit line BL in the memory cell array 1, a data latch circuit (data storage circuit) 22 that latches data to be written, an NMOS transistor 20a, a bit line clamping NMOS transistor 20b, a bit line selecting NMOS transistor 20c, and a PMOS transistor 20d.

One end of a current path of the NMOS transistor 20a is connected to a node N1 to which a power source voltage VDD is applied, and the other end of the current path thereof is connected to a node N3. A signal BLX is applied to a gate electrode of the NMOS transistor 20a. Further, one end of a current path of the bit line clamping NMOS transistor 20b is connected to the node N3, and the other end of the current path thereof is connected to one end of a current path of the bit line selecting NMOS transistor 20c. A signal BLC is applied to a gate electrode of the bit line clamping NMOS transistor 20b. An electric potential level of the bit line BL is determined by an electric potential applied to the NMOS transistor 20b. One end of a current path of the bit line selecting NMOS transistor 20c is connected to the other end of the current path of the bit line clamping NMOS transistor 20b, and the other end of the current path thereof is connected to a node N8. A bit line selecting signal BLS is applied to a gate electrode of the bit line selecting NMOS transistor 20c. The power source voltage VDD is applied to one end of a current path of the PMOS transistor 20d, and the other end of the current path thereof is connected to a node N5. A signal PCn is applied to a gate electrode of the PMOS transistor 20d. The sense module 20 is connected to the memory string.

The bit line selecting transistor 20c receives the input of the bit line selecting signal BLS through the gate, and controls on and off of the sense module 20. Here, the signal BLS is given from the control circuit 7.

The sense amplifier 21 includes NMOS transistors 21a, 21b, 21c, 21e, and 21f, and a capacitor 21d.

One end of a current path of the NMOS transistor 21a is connected to the node N1 to which the power source voltage VDD is applied, and the other end of the current path thereof is connected to a node N2 (referred to as a sense node, and may also be denoted as SEN). A signal HLL is applied to a gate electrode of the NMOS transistor 21a. Further, one end of a current path of the NMOS transistor 21b is connected to the node N2, and the other end of the current path thereof is connected to the node N3. A signal XXL is applied to a gate electrode of the NMOS transistor 21b. One end of a current path of the NMOS transistor 21c is connected to the node N5, and the other end of the current path thereof is connected to the node N2 (SEN). A signal BLQ is applied to agate electrode of the NMOS transistor 21c. One end of the capacitor 21d is connected to the node N2 (SEN), and the other end thereof is connected to a node N4 to which a signal CLK is input. One end of a current path of the NMOS transistor 21e is connected to the node N5, and the other end of the current path thereof is connected to one end of a current path of the NMOS transistor 21f. A signal STB is applied to a gate electrode of the NMOS transistor 21e. The one end of the current path of the NMOS transistor 21f (also referred to as a sense transistor) is connected to the other end of the current path of the NMOS transistor 21e, and the other end of the current path thereof is connected to the node N4. A gate electrode of the NMOS transistor 21f is connected to the node N2 (SEN). Data is sensed by the NMOS transistor 21f.

The data latch circuit 22 includes NMOS transistors 22a, 22d, 22g, and 22h, and PMOS transistors 22b, 22c, 22e, and 22f.

One end of a current path of the NMOS transistor 22a is connected to the node N5, and the other end of the current path thereof is connected to a node N6. A signal STL is applied to a gate electrode of the NMOS transistor 22a. One end of a current path of the PMOS transistor 22b is supplied with the power source voltage VDD, and the other end of the current path thereof is connected to one end of a current path of the PMOS transistor 22c. A signal SLL is applied to a gate electrode of the PMOS transistor 22b. One end of a current path of the PMOS transistor 22c is connected to the other end of the current path of the PMOS transistor 22b, and the other end of the current path thereof is connected to the node N6. A gate electrode of the PMOS transistor 22c is connected to a node N7. One end of a current path of the NMOS transistor 22d is connected to the node N6, and the other end of the current path thereof is connected to a ground potential (GND). A gate electrode of the NMOS transistor 22d is connected to the node N7. One end of a current path of the PMOS transistor 22e is supplied with the power source voltage VDD, and the other end of the current path thereof is connected to one end of a current path of the PMOS transistor 22f. A signal SLI is applied to a gate electrode of the PMOS transistor 22e. One end of a current path of the PMOS transistor 22f is connected to the other end of the current path of the PMOS transistor 22e, and the other end of the current path thereof is connected to the node N7. A gate electrode of the PMOS transistor 22f is connected to the node N6. One end of a current path of the NMOS transistor 22g is connected to the node N7, and the other end of the current path thereof is connected to the ground potential (GND). A gate electrode of the NMOS transistor 22g is connected to the node N6. One end of a current path of the NMOS transistor 22h is connected to the node N5, and the other end of the current path thereof is connected to the node N7. A signal STI is applied to a gate electrode of the NMOS transistor 22h.

Configuration of CLK Generating Circuit

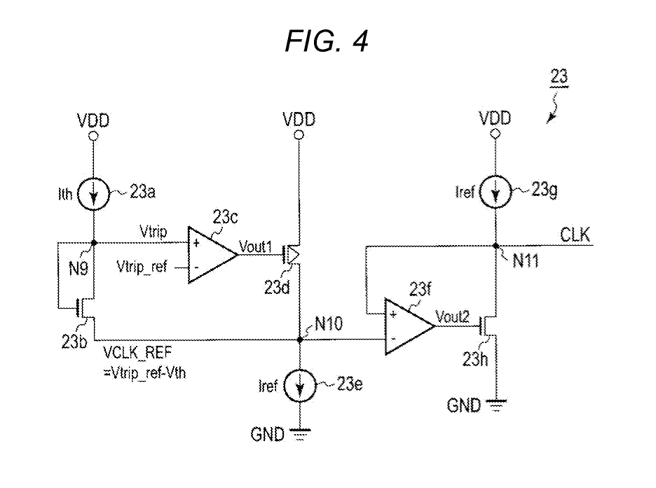

Next, a CLK generating circuit 23 that generates the signal CLK supplied to the node N4 will be described with reference to FIG. 4.

The CLK generating circuit 23 includes a constant current source 23a, an NMOS transistor 23b, an operational amplifier 23c, a PMOS transistor 23d, a constant current source 23e, an operational amplifier 23f, a constant current source 23g, and an NMOS transistor 23h. Here, the NMOS transistor 23b and the NMOS transistor 23h are replica transistors of the NMOS transistor 21f of the sense amplifier 21. It is preferable that the NMOS transistor 23b and the NMOS transistor 23h are made under the same conditions as in the NMOS transistor 21f.

The constant current source 23a is supplied with the power source voltage VDD, and outputs a threshold current Ith to a node N9. One end of a current path of the NMOS transistor 23b is connected to the node N9, and the other end of the current path thereof is connected to a node N10. A gate electrode of the NMOS transistor 23b is connected to the node N9. A non-inverted input terminal of the operational amplifier 23c is connected to the node N9, and an inverted input terminal thereof is supplied with a voltage Vtrip_ref. The operational amplifier 23c outputs an operational result as a voltage Vout1. One end of a current path of the PMOS transistor 23d is supplied with the power source voltage VDD, and the other end of the current path thereof is connected to the node N10. The output voltage Vout1 of the operational amplifier 23c is applied to a gate of the PMOS transistor 23d. The constant current source 23e is connected to the node N10 at an input end thereof, and outputs a reference current Iref to the ground potential GND.

A non-inverted input terminal of the operational amplifier 23f is connected to a node N11, and an inverted input terminal thereof is connected to the node N10. The operational amplifier 23f outputs an operational result as a voltage Vout2. The constant current source 23g is supplied with the power source voltage VDD, and outputs the reference current Iref to the node N11. One end of a current path of the NMOS transistor 23h is connected to the node N11, and the other end of the current path thereof is connected to the ground potential GND. The voltage Vout2 is applied to a gate of the NMOS transistor 23h.

As the control circuit 7 supplies the power source voltage VDD to the CLK generating circuit 23, an electric potential VCLK (Vtrip_ref−Vthn) is generated as the signal CLK at the node N11. Here, the reference voltage Vtrip_ref is a fixed value, and a threshold voltage Vthn is the same threshold voltage (a threshold voltage of the NMOS transistor 23b) as a threshold voltage of the NMOS transistor 21f. The threshold voltage Vthn is changed according to the temperature of the semiconductor memory device 100. As a result, the electric potential VCLK (Vtrip_ref−Vthn) is changed according to the temperature of the semiconductor memory device 100.

Operation of Sense Module

For example, in a sense operation according to the present embodiment, the sense amplifier 21 senses, during data reading, a current Icell (on) that flows as the memory cell MC is in a turned-on state, that is, as the bit line BL and the source line SL are in a conductive state, to determine the read data as ‘1’. On the other hand, when the memory cell MC is in a turned-off state, that is, when the bit line BL and the source line SL are in a non-conductive state, the sense amplifier 21 senses a current Icell (off) to determine the read data as ‘0’.

Further, in the sense operation according to the present embodiment, the sense amplifier 21 is controlled by the control circuit 7 so that the electric potential of the node N3 is not changed immediately before and immediately after the sense amplifier 21 starts the sensing of the memory cell array 1. Further, in the sense operation according to the present embodiment, when determining a threshold value of the sensed data, the electric potential VCLK (Vtrip_ref−Vthn) is generated by the CLK generating circuit 23, in consideration of change of the threshold value due to the temperature of the semiconductor memory device 100, for example. Thus, it is possible to suppress a variation of the threshold value of the NMOS transistor 21f (sense transistor) in the sense operation.

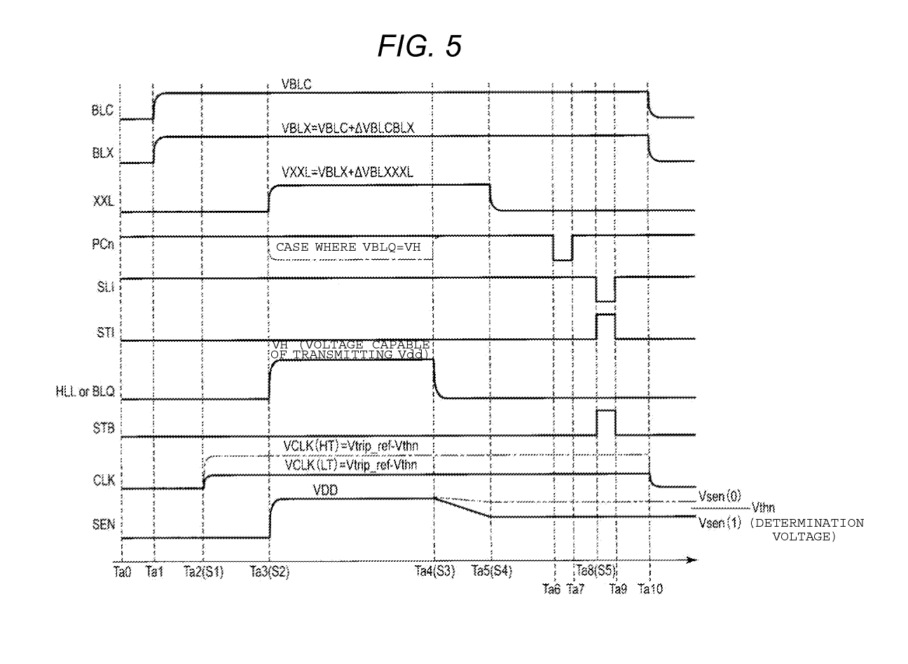

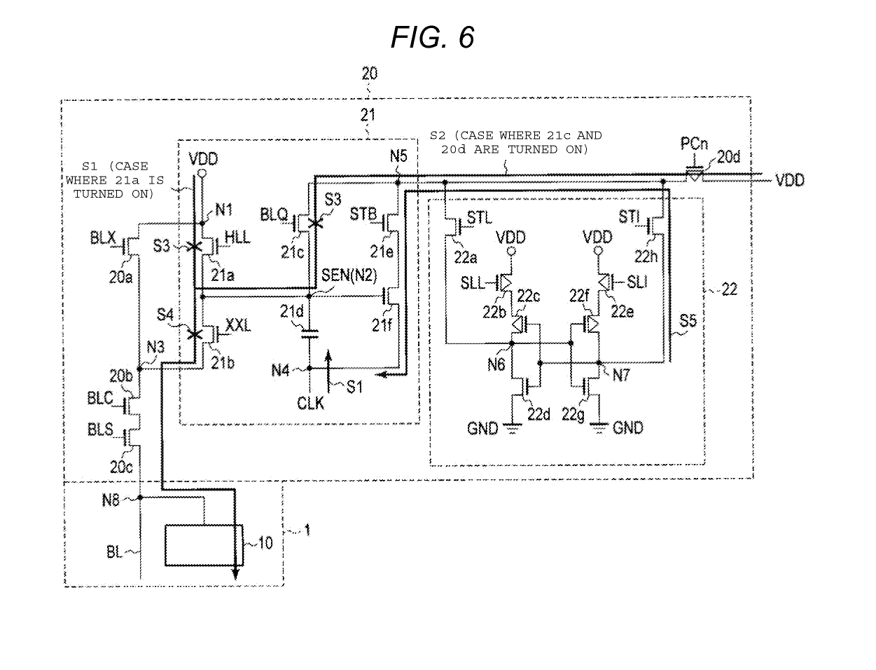

An operation of the sense module 20 in the data sense operation will be described with reference to FIGS. 5 and 6.

Time Ta0

At time Ta0, the electric potentials of the signals BLC, BLX, XXL, STI, HLL (or BLQ), STB, CLK, and SEN are at an “L (low)” level. Further, the electric potentials of the signals PCn and SLI are at an “H (high)” level. Thus, the NMOS transistors 20a, 20b, 21a, 21b, 21c, 21e, 21f, and 22h and the PMOS transistors 20d and 22e are turned off. The signals BLX, XXL, STI, HLL, BLQ, STB, PCn and SLI are controlled by the control circuit 7. Here, an electric potential level at which the NMOS transistors are turned off or the PMOS transistors are turned on is referred to as the “L” level for the sake of convenience. Further, an electric potential level at which the NMOS transistors are turned on or the PMOS transistors are turned off is referred to as the “H” level.

Time Ta1

At time Ta1, the control circuit 7 increases an electric potential VBLC of the signal BLC from the “L” level to the “H” level. The control circuit 7 increases an electric potential VBLX of the signal BLX from the “L” level to the “H” level (electric potential VBLX=VBLC (“H”)+ΔBLCBLX). Thus, the NMOS transistors 20a and 20b are turned on. Further, the control circuit 7 increases an electric potential of the signal BLS from the “L” level to the “H” level. Thus, the NMOS transistor 20c is turned on.

Time Ta2: Step S1

At time Ta2, the control circuit 7 supplies the power source voltage VDD to the CLK generating circuit 23 shown in FIG. 4, to thereby set the electric potential VCLK of the signal CLK that reflects the threshold value of the NMOS transistor 21f to Vtrip_ref−Vthn. As described above, the electric potential VCLK (Vtrip_ref−Vthn) is changed according to the temperature of the semiconductor memory device 100. For example, the electric potential VCLK (HT) at a high temperature is higher than the electric potential VCLK (LT) at a low temperature. Thus, the node N4 of the sense amplifier 21 is charged to the electric potential VCLK (Vtrip_ref−Vthn).

Time Ta3: Step S2

At time Ta3, the control circuit 7 increases an electric potential VXXL of the signal XXL from the “L” level to the “H” level (VXXL=VBLX (“H”)+ΔVBLXXXL). Thus, the NMOS transistor 21b is turned on.

The control circuit 7 increases an electric potential VHLL of the signal HLL or an electric potential VBLQ of the signal BLQ from the “L” level to the “H” level (VH: electric potential capable of transmitting the power source voltage VDD). Thus, the NMOS transistor 21a or 21c is turned on.

Further, when turning on the NMOS transistor 21c, the control circuit 7 decreases an electric potential of the signal PCn from the “H” level to the “L” level. Thus, the PMOS transistor 20d is turned on.

Thus, the power source voltage VDD is supplied to the node N2 (SEN), and thus, the node N2 (SEN) is charged to the electric potential VDD. In this manner, in the present embodiment, the node N2 (SEN) is charged in a state where the NMOS transistor 21b is turned on.

Time Ta4: Step S3

At time Ta4, when the electric potential VHLL of the signal HLL is the “H” level, the control circuit 7 decreases the electric potential VHLL of the signal HLL from the “H” level to the “L” level. Thus, the NMOS transistor 21a is turned off. Further, when the electric potential VBLQ of the signal BLQ is the “H” level, the control circuit 7 decreases the electric potential VBLQ of the signal BLQ from the “H” level to the “L” level. Thus, the NMOS transistor 21c is turned off. Further, when the electric potential VPCn of the signal PCn is the “L” level, the control circuit 7 increases the electric potential VPCn of the signal PCn from the “L” level to the “H” level. Thus, the PMOS transistor 20d is turned off.

In this manner, the control circuit 7 starts the sense operation of the memory string 10. The electric potential of the node N2 decreases to an electric potential that depends on a current (also referred to as a cell current or the like) that flows in the bit line BL.

In the present embodiment, the control circuit 7 starts the sense operation while maintaining the node N3 and the node N2 in the conductive state. Thus, the electric potential of the node N3 is not changed before and after the sense operation is started.

Time Ta5: Step S4

At time Ta5 after a predetermined time elapses from time Ta4, the control circuit 7 decreases the electric potential VXXL of the signal XXL from the “H” level to the “L” level. Thus, as shown in FIG. 6, the NMOS transistor 21b is turned off, and the current supply to the memory string 10 is stopped.

Between time Ta4 and time Ta5, the electric potential of the node N2 (SEN) is changed based on the cell current that flows in the memory cell MC. For example, when an electric potential obtained by subtracting the electric potential VCLK charged at the node N4 from the electric potential Vsen of the node N2 (SEN) is lower than the threshold voltage Vthn (Vsen−VCLK<Vthn), the sense amplifier 21 determines the read data as “1”. Further, when the electric potential obtained by subtracting the electric potential VCLK charged at the node N4 from the electric potential Vsen of the node N2 (SEN) is higher than the threshold voltage Vthn (Vsen−VCLK>Vthn), the sense amplifier 21 determines the read data as “0”. That is, it is determined whether the data is “0” or “1” according to the amount of change in the electric potential of the node N2.

Time Ta6

At time Ta6, the control circuit 7 decreases the electric potential VPCn of the signal PCn from the “H” level to the “L” level. Thus, the PMOS transistor 20d is turned on.

Time Ta7

At time Ta7, the control circuit 7 increases the electric potential of the signal PCn from the “L” level to the “H” level. Thus, the PMOS transistor 20d is turned off.

Time Ta8: Step S5

At time Ta8, in order to transmit the data sensed at the node N2 (SEN) to the data latch circuit 22, the control circuit 7 decreases the electric potential of the signal SLI from the “H” level to the “L” level, and increases the electric potentials of the signals STI and STB from the “L” level to the “H” level. Thus, the PMOS transistor 22e and the NMOS transistors 22h and 21e are turned on. As a result, a current flows from the data latch circuit 22 to the node N4. Here, the node N4 is charged by the electric potential VCLK (Vtrip_ref−Vthn) generated to suppress the variation of the threshold value of the NMOS transistor 21f (sense transistor) in the sense operation. Thus, data that does not depend on the variation of the threshold value of the NMOS transistor 21f (sense transistor) is transmitted to the data latch circuit 22.

Time Ta9

At time Ta9, the control circuit 7 increases the electric potential of the signal SLI from the “L” level to the “H” level, and decreases the electric potentials of the signals STI and STB from the “H” level to the “L” level. Thus, the PMOS transistor 22e and the NMOS transistors 22h and 21e are turned off. Thus, the transmission of the data sensed at the node N2 (SEN) to the data latch circuit 22 is completed.

Time Ta10

At time Ta10, the control circuit 7 decreases the electric potentials of the signals BLC, BLX, and CLK from the “H” level to the “L” level.

### Effects According to the Present Embodiment

According to the above-described embodiment, before the sense operation is performed, the drain side node of the transistor that determines the electric potential level of the bit line BL and the sense node are electrically connected to each other to perform the charging operation. Further, in consideration of the variation of the threshold value due to the temperature characteristic of the sense transistor used in sensing the data, the source electric potential of the sense transistor is charged before the sense operation is performed.

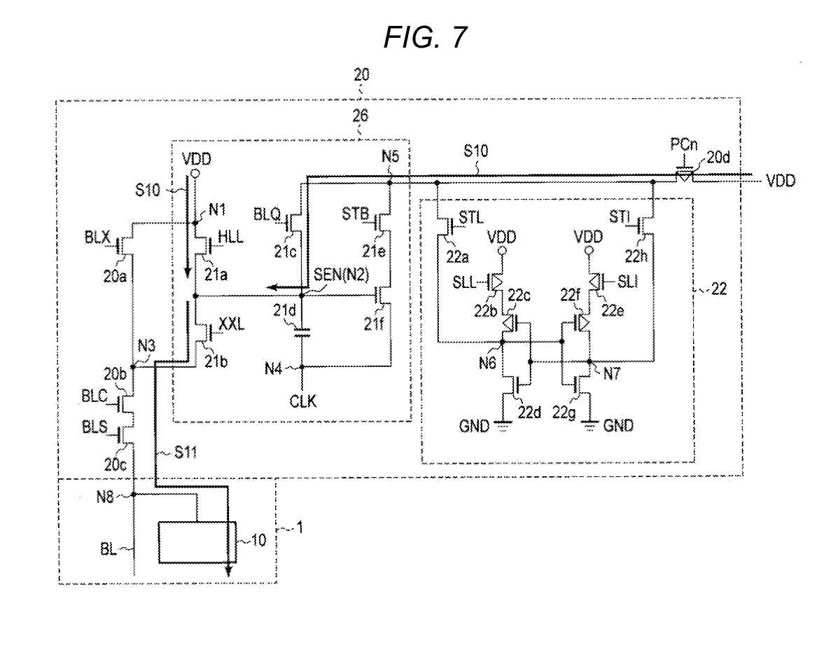

Hereinafter, for ease of understanding of the effects of the present embodiment, a comparative example will be briefly described with reference to FIGS. 7 to 9. In the comparative example, the CLK generating circuit 23 of the above-described embodiment is not provided. Further, a sense module 20 according to the comparative example is the same as the sense module 20 of the above-described embodiment, except that the CLK generating circuit 23 is not provided. Thus, the description of the same configuration of the sense module 20 according to the comparative example will not be repeated.

In the comparative example, the NMOS transistors 20a, 20b, and 21a are turned on before the sense operation is started (step S10). Thus, the electric potential of the node N2 (SEN) is charged up to VSEN-Vthn. At this time, differently from the above-described embodiment, the NMOS transistor 21b is turned off. Here, the electric potential level of the bit line BL is clamped with the signal BLC, and the electric potential level of the node N3 is clamped with the signal BLX.

Subsequently, as the NMOS transistor 21b is turned on, the cell current flows from the NMOS transistor 21b, so that the sense operation is started (step S11). At this time, even though the variation is present in the threshold value of the NMOS transistor 21b, since the cell current flows from the NMOS transistor 21b, the electric potential VXXL of the signal XXL is set to an electric potential higher than the electric potential VBLX applied to the NMOS transistor 20a by ΔVBLXXXL.

The node N3 is switched to be clamped with the signal XXL. Thus, the electric potential level of the node N3 is increased by ΔVN3 (ΔVN3=ΔVBLXXXL+Vth (NMOS transistor 21b)−Vth (NMOS transistor 20a)).

Thus, the NMOS transistor 20b receives noise of gate coupling due to the change of the electric potential of the node N3, and thus, the electric potential VBLC applied to the gate electrode of the NMOS transistor 20b is increased. Thus, the level of the bit line BL is also increased.

The sense operation is performed as the node N2 (SEN) is discharged. However, in the sense operation according to the comparative example, charges of the node N2 (SEN) are used to increase the electric potential of the node N3. Thus, such movement of the charges leads to sense noise.

However, in the sense module 20 according to the above-described embodiment, since the node N3 and the node N2 (SEN) are electrically connected to each other before the sense operation is performed, it is possible to suppress the variety of noise as mentioned above when the sense operation is started.

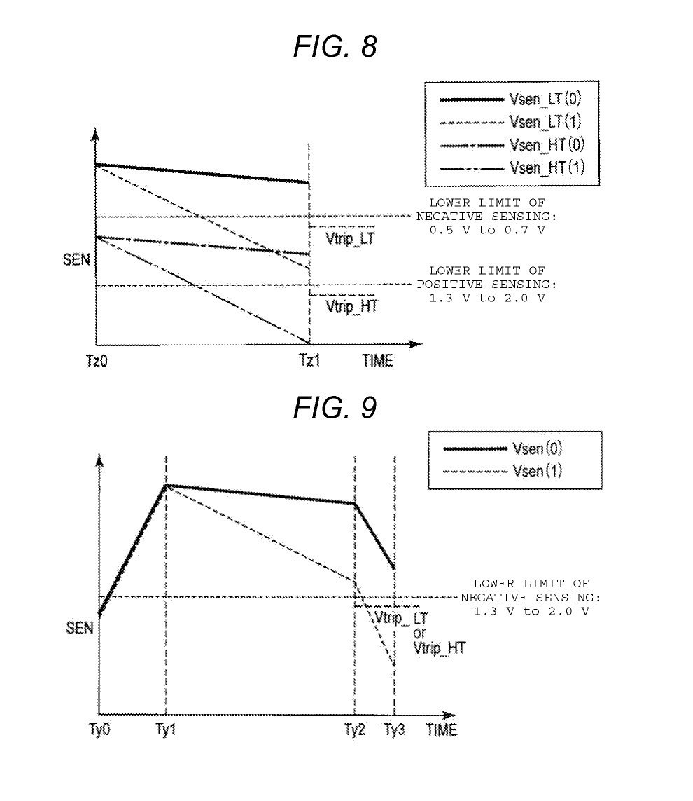

Next, as shown in FIG. 8, a data determination potential Vtrip is changed depending on the change of the threshold potential Vth due to the temperature of the NMOS transistor 21f or the like. For example, an electric potential Vsen_LT (0) of the node N2 at a low temperature is higher than an electric potential Vsen_HT (0) of the node N2 at a high temperature. Similarly, an electric potential Vsen_LT (1) of the node N2 at a low temperature is higher than an electric potential Vsen_HT (1) of the node N2 at a high temperature.

As shown in FIG. 8, a determination potential Vtrip HT at a high temperature is lower than a determination potential Vtrip LT at a low temperature. In this regard, as the sense operation, there are a positive sensing method and a negative sensing method. For example, in the case of the positive sensing method, a lower limit potential (positive lower limit potential) of the node N2 (SEN) is 0.5 V to 0.7 V. When the determination potential is lower than the positive lower limit potential, the sense module 20 cannot sense the data.

Further, in the case of the negative sensing method, a lower limit potential (negative lower limit potential) of the node N2 (SEN) is 1.3 V to 2.0 V. When the determination potential is lower than the negative lower limit potential, the sense module 20 cannot sense the data.

As shown in FIG. 8, in the negative sensing method, the negative lower limit potential is higher than the determination potential Vtrip_LT at the low temperature. Thus, as shown in FIG. 9, the signal CLK is charged to a certain electric potential before the data is sensed (before the sense node is discharged by the cell current). Accordingly, the electric potential level of the sense node is increased due to coupling of the capacitance element. In this state, the sense node is discharged by the cell current, and then, the NMOS transistor 21b is turned off. Thus, the sense operation is terminated. At this time, the sense node is equal to or higher than the lower limit potential. However, thereafter, the electric potential level of the sense node decreases due to the coupling of the capacitance element by decreasing the electric potential of the signal CLK to the original level, so that Vsen (1) can be decreased to the determination potential or lower. Thus, even though there is the lower limit potential in the discharge operation, the transmission operation to the data latch circuit can be realized without interference. Thus, even though there is the lower limit potential in the discharge operation due to the cell current, it is possible to realize the negative sensing method.

In the sense module 20 according to the comparative example, the CLK generating circuit 23 described in the above-described embodiment is not provided. Thus, even when the electric potential is applied to the node N4, the electric potential that reflects the temperature characteristic or the like of the NMOS transistor 21f cannot be applied, and only the set electric potential can be applied.

However, according to the CLK generating circuit 23 of the above-described embodiment, the source line potential of the NMOS transistor 21f can be appropriately increased according to the change of the threshold value due to the temperature characteristic of the NMOS transistor 21f.

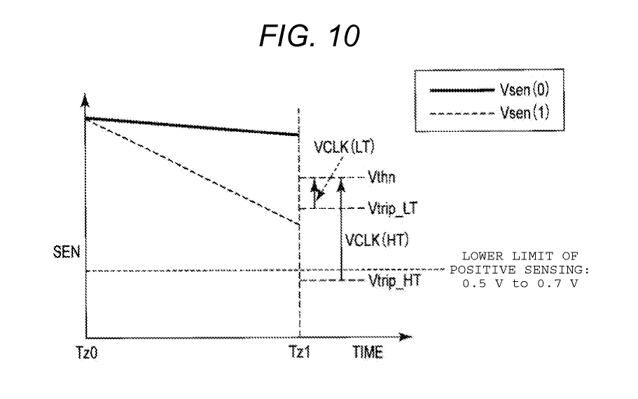

Thus, as shown in FIG. 10, it is possible to compensate the change of the determination potential Vtrip due to the temperature in advance. As a result, it is possible to prevent the determination potential from being lower than at least the positive lower limit potential. Further, even though the temperature is changed, it is possible to stably perform the sense operation.

As described above, according to the semiconductor memory device according to the above-described embodiment, it is possible to provide a high quality semiconductor memory device capable of suppressing the above-mentioned noise and capable of suppressing the variation of the threshold value of the sense transistor due to the temperature change.

The positive sensing method is effective in that necessary voltage consumption is small and it is not necessary to provide a voltage generating circuit for performing the negative sensing method, compared with the negative sensing method.

### Second Embodiment

Next, a semiconductor memory device according to a second embodiment will be described. In the second embodiment, in the sense module described in the first embodiment, a sense operation in a case where the negative sensing method is employed as the sense operation will be described. A basic configuration and operation of the second embodiment is the same as the configuration and operation of the first embodiment. Thus, in the second embodiment, the same reference numerals are given to components having approximately the same function and configuration as those of the first embodiment, and repetitive description will be made only as necessary.

Detailed operation of the negative sensing method is disclosed in U.S. Pat. No. 7,046,568 filed on Dec. 16, 2004 “Memory sensing circuit and method for low voltage operation”, for example. The entire content of this patent application is incorporated herein by reference.

Operation of Sense Module According to Second Embodiment

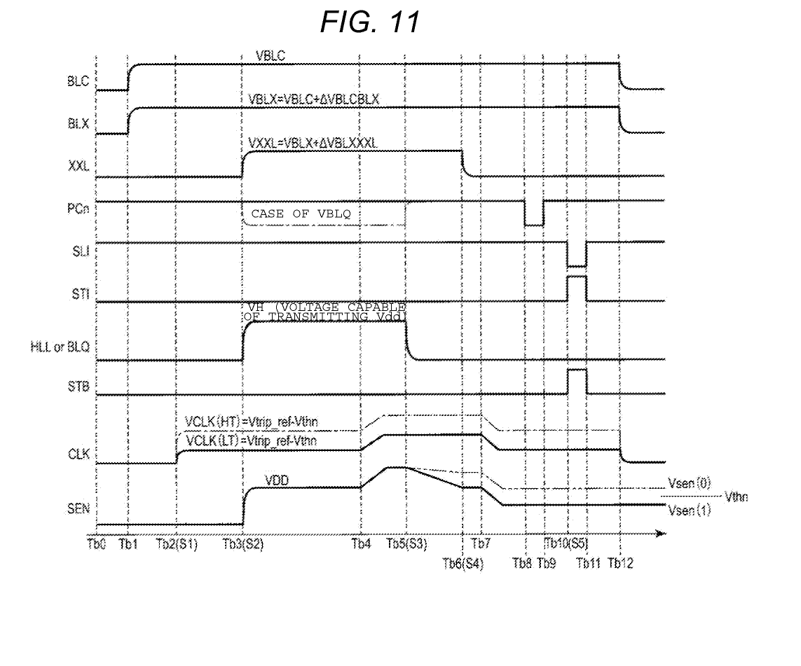

An operation of the sense module 20 in the data sense operation will be described with reference to FIG. 11.

Times Tb0 to Tb3

Operations at times Tb0 to Tb3 are the same as the operations at times Ta0 to Ta3 described in the first embodiment.

Time Tb4

At time Tb4, the control circuit 7 increases the electric potential VCLK by an electric potential ΔVCLKN in order to perform the negative sensing method described with reference to FIG. 9. Thus, even though there is the lower limit in the discharge operation due to the cell current, no problem occurs.

Time Tb5

At time Tb5, the NMOS transistor 21a or the NMOS transistor 21c are turned off to start the sense operation.

Time Tb6

Further, at time Tb6, the NMOS transistor 21b is turned off to terminate the sense operation.

Time Tb7

Furthermore, at time Tb7, the electric potential VCLK is decreased by the electric potential ΔVCLKN before the data is transmitted to the data latch circuit 22. Thus, it is possible to determine the data at a voltage lower than the negative lower limit potential.

Times Tb8 to Tb12

Operations at times Tb8 to Tb12 are the same as the operations at times Ta6 to Ta10 described in the first embodiment.

### Effects According to the Second Embodiment

According to the above-described embodiment, it is possible to perform the negative sense operation, in addition to the positive sense operation, for the sense module 20 described in the first embodiment.

### Third Embodiment

Next, a semiconductor memory device according to a third embodiment will be described. In the third embodiment, a configuration and operation of a sense module including a circuit different from the sense module described in the first embodiment will be described. In the third embodiment, the same reference numerals are given to components having approximately the same function and configuration as those of the first embodiment, and repetitive description will be made only as necessary.

Configuration of Sense Module

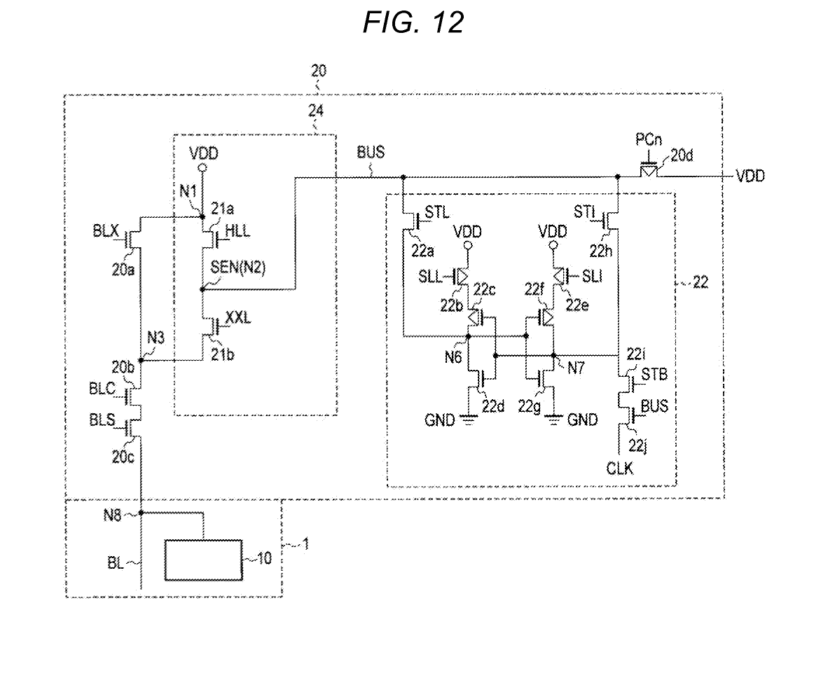

Next, a basic configuration of the sense module 20 according to the present embodiment will be briefly described with reference to FIG. 12.

The sense module 20 includes the sense amplifier 24, the data latch circuit 22, the NMOS transistor 20a, the bit line clamping NMOS transistor 20b, the bit line selecting NMOS transistor 20c, and the PMOS transistor 20d.

The sense amplifier 24 includes the NMOS transistors 21a and 21b.

The data latch circuit 22 includes NMOS transistors 22a, 22d, 22g, 22h, 22i, and 22j, and PMOS transistors 22b, 22c, 22e, and 22f.

One end of a current path of the NMOS transistor 22i is connected to the node N7, and the other end of the current path of the NMOS transistor 22i is connected to one end of a current path of the NMOS transistor 22j. The signal STB is applied to a gate electrode of the NMOS transistor 22i. Further, one end of a current path of the NMOS transistor 22j (sense transistor) is connected to the other end of the current path of the NMOS transistor 21i, and the signal CLK is applied to the other end of the current path thereof from the CLK generating circuit 23. Agate electrode of the NMOS transistor 22j is connected to a bus connected to the node N2.

Operation of Sense Module According to Third Embodiment

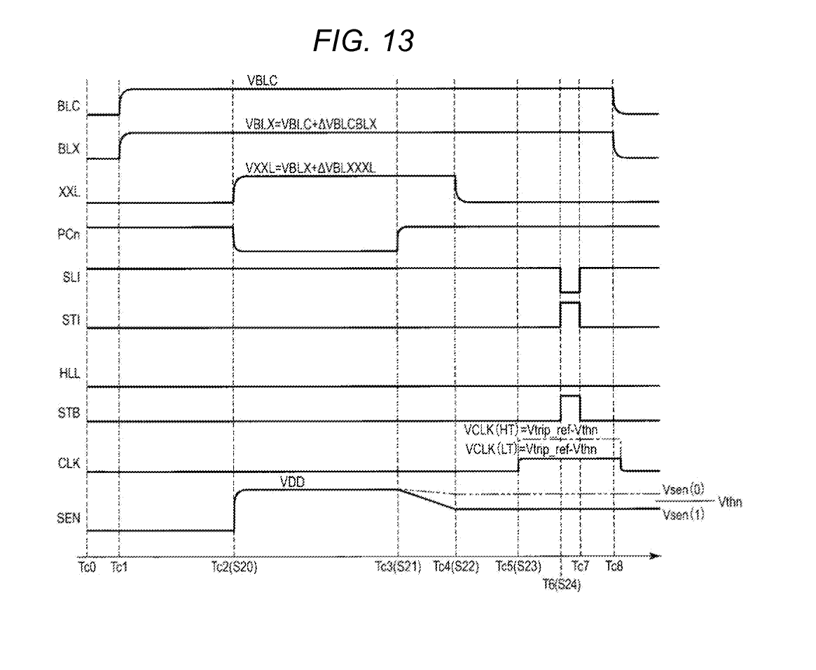

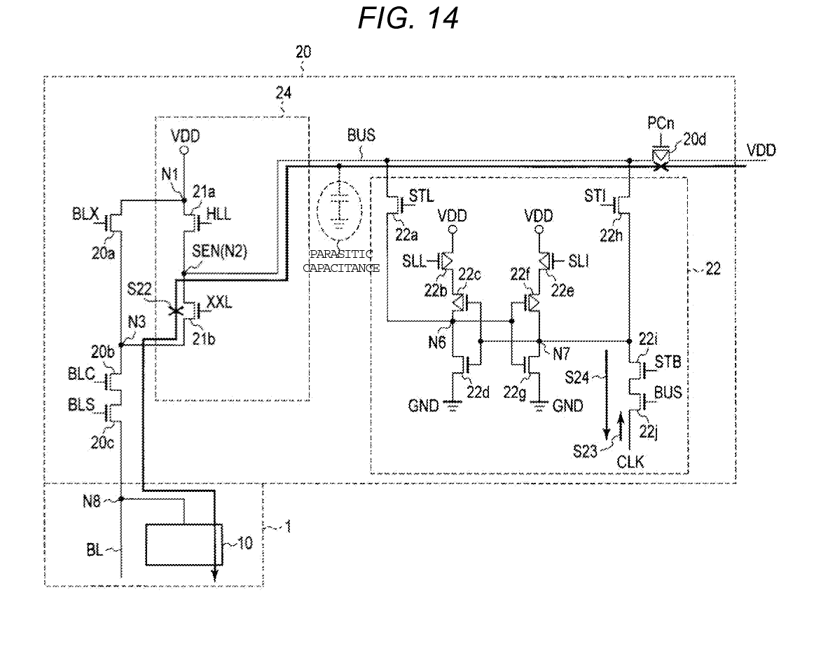

Next, an operation of the sense module 20 in the data sense operation will be described with reference to FIGS. 13 and 14.

Times Tc0 and Tc1

Operations at times Tc0 and Tc1 are the same as the operations at times Ta0 and Ta1 described in the first embodiment.

Time Tc2: step S20

At time Tc2, the control circuit 7 increases the electric potential VXXL of the signal XXL from the “L” level to the “H” level (VXXL=VBLX (“H”)+ΔVBLXXXL). Thus, the NMOS transistor 21b is turned on.

The control circuit 7 decreases the electric potential of the signal PCn from the “H” level to the “L” level. Thus, the PMOS transistor 20d is turned on.

Thus, the power source voltage VDD is supplied to the node N2 (SEN), and thus, the node N2 (SEN) is charged to the electric potential VDD. In this manner, in the present embodiment, the node N2 (SEN) is charged in a state where the NMOS transistor 21b is turned on, similar to the first embodiment.

Time Tc3: Step S21

At time Tc3, the control circuit 7 increases the electric potential VPCn of the signal PCn from the “L” level to the “H” level. Thus, the PMOS transistor 20d is turned off.

In this manner, the control circuit 7 starts the sense operation of the memory string 10. Here, the sense operation is performed using a parasitic capacitance of a bus that is the node N2 as the capacitor 21d shown in the first embodiment.

Time Tc4: Step S22

An operation at time Tc4 is the same as the operation at time Ta5 described in the above first embodiment.

Time Tc5: Step S23

At time Tc5, before the sensed data is transmitted to the data latch circuit 22, the control circuit 7 generates the electric potential VCLK (Vtrip_ref−Vthn) using the CLK generating circuit 23, and charges the source electric potential of the NMOS transistor 22j to the electric potential VCLK (Vtrip_ref−Vthn).

As described in the first embodiment, the electric potential VCLK (Vtrip_ref−Vthn) is changed according to the temperature of the semiconductor memory device 100. For example, the electric potential VCLK (HT) at a high temperature is higher than the electric potential VCLK (LT) at a low temperature.

Times Tc6 to Tc8: Step S24

Operations at times Tc6 to Tc8 are the same as the operations at times Ta8 to Ta10 described in the above first embodiment.

### Effects According to Third Embodiment

According to the above-described embodiment, the sense transistor is embedded in the data latch circuit 22. Further, the parasitic capacitance of the bus that is the node N2 is used as the capacitor of the sense amplifier 24.

In the above-described first and second embodiments, the node N4 to which the electric potential VCLK is applied is connected to the capacitor 21d. Thus, in the first and second embodiments, if the node N4 is charged up to the electric potential VCLK after the sense operation is started, sense noise is generated due to coupling. However, according to the third embodiment, instead of the capacitor 21d, the parasitic capacitance of the bus is used. Thus, even though the electric potential of the source of the NMOS transistor 22j is changed during the sense operation, the sense noise is not generated. In the above-described third embodiment, the control circuit 7 generates the electric potential VCLK (Vtrip_ref−Vthn) immediately before the data is transmitted to the data latch circuit 22. In this manner, in the third embodiment, restriction of the timing when the electric potential VCLK is generated is alleviated, compared with the above-described first and second embodiments.

Further, since the capacitor 21d is not necessary in the third embodiment, the circuit area becomes small compared with the sense module described in the first and second embodiments.

### Fourth Embodiment

Next, a semiconductor memory device according to a fourth embodiment will be described. In the fourth embodiment, a configuration of another example of the CLK generating circuit will be described. In the fourth embodiment, the description of components having the approximately the same function and configuration as those of the above-described first embodiment will not be repeated.

Configuration of CLK Generating Circuit

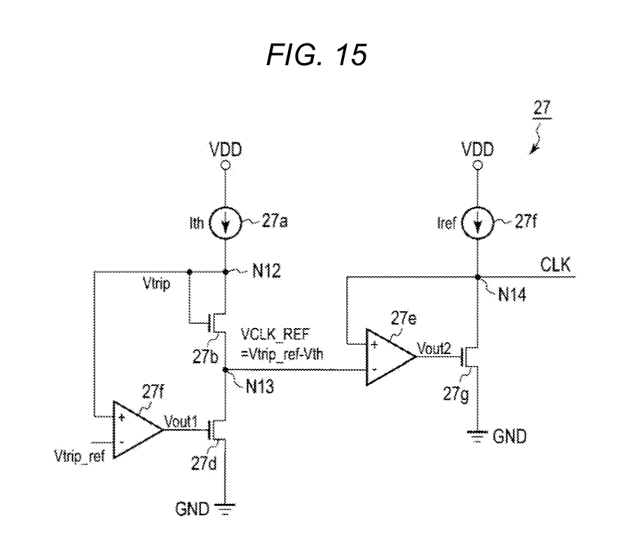

A CLK generating circuit 27 that generates the signal CLK supplied to the node N4 in the first and second embodiments or the source side of the NMOS transistor 22j in the third embodiment will be described with reference to FIG. 15.

The CLK generating circuit 27 includes a constant current source 27a, an NMOS transistor 27b, an operational amplifier 27c, an NMOS transistor 27d, an operational amplifier 27e, a constant current source 27f, and an NMOS transistor 27g. The NMOS transistor 27b and the NMOS transistor 27g are replica transistors of the NMOS transistor 21f of the sense amplifier 21 or the NMOS transistor 22j of the data latch circuit 22. It is preferable that the NMOS transistor 27b and the NMOS transistor 27g be manufactured under the same conditions as in the NMOS transistor 21f or the NMOS transistor 22j of the data latch circuit 22.

The constant current source 27a is supplied with the power source voltage VDD, and outputs a threshold current Ith to a node N12. One end of a current path of the NMOS transistor 27b is connected to the node N12, and the other end of the current path thereof is connected to a node N13. A gate electrode of the NMOS transistor 27b is connected to the node N12. A non-inverted input terminal of the operational amplifier 27c is connected to the node N12, and an inverted input terminal thereof is supplied with a voltage Vtrip_ref. The operational amplifier 27c outputs an operational result as a voltage Vout1. One end of a current path of the NMOS transistor 27d is connected to the node N13, and the other end of the current path thereof is connected to the ground potential GND. The output voltage Vout1 of the operational amplifier 27c is applied to a gate of the NMOS transistor 27d.

A non-inverted input terminal of the operational amplifier 27e is connected to the node N13, and an inverted input terminal thereof is connected to a node N14. The operational amplifier 27e outputs an operational result as a voltage Vout2. The constant current source 27f is supplied with the power source voltage VDD, and outputs a reference current Iref to the node N14. One end of a current path of the NMOS transistor 27g is connected to the node N14, and the other end of the current path thereof is connected to the ground potential GND. The voltage Vout2 is applied to a gate of the NMOS transistor 27g.

As the control circuit 7 supplies the power source voltage VDD to the CLK generating circuit 27, the electric potential VCLK (Vtrip_ref-Vthn) is generated as the signal CLK at the node N14.

### Modification Examples and the Like

When the negative sensing method is performed by the sense module 20 according to the above-described third embodiment, it is possible to apply the negative sensing method shown in the second embodiment to the third embodiment.

(1) In each embodiment, in the read operation, a voltage applied to the word line selected in the read operation of a level “A” is between 0 V and 0.55 V, for example. The voltage is not limited thereto, and may be set to any value between 0.1 V and 0.24 V, between 0.21 V and 0.31 V, between 0.31 V and 0.4 V, between 0.4 V and 0.5 V, and between 0.5 V and 0.55 V.

A voltage applied to the word line selected in the read operation of a level “B” is between 1.5 V and 2.3 V, for example. The voltage is not limited thereto, and may be set to any value between 1.65 V and 1.8 V, between 1.8 V and 1.95 V, between 1.95 V and 2.1 V, and between 2.1 V and 2.3 V.

A voltage applied to the word line selected in the read operation of a level “C” is between 3.0 V and 4.0 V, for example. The voltage is not limited thereto, and may be set to any value between 3.0 V and 3.2 V, between 3.2 V and 3.4 V, between 3.4 V and 3.5 V, between 3.5 V and 3.6 V, and between 3.6 V and 4.0 V.

A time (tR) of the read operation may be set between 25 μs and 38 μs, between 38 μs and 70 μs, and between 70 μs and 80 μs, for example.

(2) In each embodiment, the write operation includes the program operation and the verify operation, as described above. In the write operation, a voltage initially applied to the word line selected in the program operation is between 13.7 V and 14.3 V, for example. The voltage is not limited thereto, and may be set to any value between 13.7 V and 14.0 V, and between 14.0 V and 14.6 V, for example.

A voltage initially applied to the selected word line in writing of an odd-numbered word line may be changed to a voltage initially applied to the selected word line in writing of an even-numbered word line.

When the program operation uses an incremental step pulse program (ISPP) method, for example, about 0.5 V is used as a step-up voltage.

A voltage applied to a non-selected word line, for example, may be between 6.0 V and 7.3 V. The voltage is not limited thereto, and for example, may be set between 7.3 V and 8.4 V, and may be set to 6.0 V or less.

A path voltage to be applied may be changed depending on whether the non-selected word line is the odd-numbered word line or the even-numbered word line.

A time (tProg) of the write operation may be set between 1,700 μs and 1,800 μs, between 1,800 μs and 1,900 μs, and between 1,900 μs and 2,000 μs, for example.

(3) In each embodiment, in the erase operation, a voltage initially applied to a well formed on the semiconductor substrate, on which the memory cells are arranged, is between 12 V and 13.6 V, for example. The voltage is not limited thereto, and may be set between 13.6 V and 14.8 V, between 14.8 V and 19.0 V, between 19.0 V and 19.8 V, and between 19.8 V and 21 V, for example.

A time (tErase) of the erase operation may be set between 3,000 μs and 4,000 μs, between 4,000 μs and 5,000 μs, and between 4,000 μs and 9,000 μs, for example.

(4) In each embodiment, the structure of the memory cell includes a charge storage layer arranged on the semiconductor substrate (silicon substrate) through a tunnel insulating film having a film thickness of 4 nm to 10 nm. The charge storage layer may have a structure in which an insulating film of SiN, SiON or the like having a film thickness of 2 nm to 3 nm and polysilicon having a film thickness of 3 nm to 8 nm are layered. Further, a metal such as Ru may be added to the polysilicon. An insulating film is provided on the charge storage layer. The insulating film includes a silicon oxide film having a thickness of 4 nm to 10 nm, which is interposed between a lower High-k film having a thickness of 3 nm to 10 nm and an upper High-k film having a thickness of 3 nm to 10 nm. HfO or the like may be used as the High-k film. Further, the film thickness of the silicon oxide film may be thicker than the film thickness of the High-k film. A control electrode having a film thickness of 30 nm to 70 nm is formed on the insulating film through a work function adjustment material having a film thickness of 3 nm to 10 nm. Here, the work function adjustment material is a metal oxide film such as TaO, or a metal nitride film such as TaN. The control electrode may include a metal such as W.

Further, an air gap may be formed between the memory cells.

Further, the fourth embodiment may be applied to the first to third embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell;
a bit line that is electrically connected to the memory cell;
a sense module that includes a first transistor, a sense node electrically connected to the bit line through the first transistor, a second transistor electrically connected between a power source and the sense node, and a voltage generating circuit capable of generating a voltage that is equal to the first voltage minus a threshold voltage of the second transistor; and
a control circuit configured to turn on the first transistor for a period of time prior to performing a sense operation on the bit line through the sense module.

2. The device according to claim 1, wherein the sense module further includes a latch circuit, and a third transistor electrically connected between the latch circuit and the sense node.

3. The device according to claim 2, wherein the sense module further includes the voltage generating circuit and a capacitor electrically connected between the voltage generating circuit and the sense node.

4. The device according to claim 3, wherein the voltage generating circuit is configured to output a first voltage when the operating temperature is a first temperature and a second voltage lower than the first voltage when the operating temperature is a second temperature, the first temperature being higher than the second temperature.

5. The device according to claim 1, wherein the sense module further includes a latch circuit and a bus that directly connects the sense node to the latch circuit.

6. The device according to claim 5, wherein the latch circuit includes the voltage generating circuit and a series of transistors connected between the bus and the voltage generating circuit.

7. The device according to claim 6, wherein the voltage generating circuit is configured to output a first voltage when the operating temperature is a first temperature and a second voltage lower than the first voltage when the operating temperature is a second temperature, the first temperature being higher than the second temperature.

8. A semiconductor memory device comprising:
a memory cell;
a bit line that is electrically connected to the memory cell;
a sense module that includes a first node electrically connected to the bit line through a first transistor, a second transistor having a gate electrically connected to the first node, and a voltage generating circuit configured to generate a first voltage; and
a control circuit configured to control the sense module so that, during a sense operation, a second node electrically connected between the second transistor and the voltage generating circuit is charged to a second voltage that is equal to the first voltage minus a threshold voltage of the second transistor.

9. The device according to claim 8, wherein
the control circuit performs a charging operation of the first node in a state where the first transistor has been turned on, before the sense operation is started, and upon start of the sense operation, turns off the first transistor.

10. The device according to claim 8, wherein the sense module further includes:
a third transistor that is electrically connected to the bit line at one end thereof and to a third node at the other end thereof;
a fourth transistor that is electrically connected to the third node at one end thereof and to the first node at the other end thereof;
a fifth transistor that is electrically connected to the first node at one end thereof and is supplied with a power source voltage at the other end thereof;
a capacitor that is electrically connected to the first node at one end thereof and to the second node at the other end thereof;
a sixth transistor that is electrically connected to a fourth node at one end thereof and to the other end of the second transistor at the other end thereof; and
a data latch circuit that is electrically connected to the fourth node and is configured to latch data sensed at the first node.

11. The device according to claim 10, wherein the voltage generating circuit includes:
a first constant current source that is supplied with a power source voltage and outputs a first current to a fifth node;
a seventh transistor that is electrically connected to the fifth node at one end thereof and to a sixth node at the other end thereof, and includes a gate connected to the fifth node;
a first operational amplifier that is connected to the fifth node at a non-inverted input terminal thereof, is supplied with the second voltage at an inverted input terminal thereof, and outputs an operational result as a third voltage;
an eighth transistor that is supplied with the power source voltage at one end thereof, is electrically connected to the sixth node at the other end thereof, and includes a gate that is supplied with the third voltage;
a second constant current source that is electrically connected to the sixth node at an input end thereof and to a ground potential at an output end thereof;
a second operational amplifier that is electrically connected to a seventh node at a non-inverted input terminal thereof, is connected to the sixth node at an inverted input terminal thereof, and outputs an operational result as a fourth voltage;
a third constant current source that is supplied with the power source voltage and outputs a second current to the seventh node; and
a ninth transistor that is electrically connected to the seventh node at one end thereof and to the ground potential at the other end thereof, and includes a gate that is supplied with the fourth voltage.

12. The device according to claim 11, wherein
the seventh transistor is a replica transistor of the second transistor.

13. The device according to claim 12, wherein
the voltage generating circuit outputs the first voltage through the seventh node.

14. A method of performing a sense operation on a memory cell of a semiconductor memory device that is electrically connected to a bit line, comprising:
at a start of a first time period, pre-charging a sense node that is electrically connected to the bit line through a first transistor and turning on the first transistor to allow current to flow between the bit line and the sense node;
at a start of a second time period directly following the first time period, terminating the pre-charging of the sense node and performing a sense operation using a second transistor having a gate electrically connected to the sense node, while the current continues to flow between the bit line and the sense node; and
during the sense operation, generating a first voltage at a first node and charging a second node electrically connected between the second transistor and the first node to a second voltage that is equal to the first voltage minus a threshold voltage of the second transistor.

15. The device according to claim 14, wherein the first voltage is higher when the operating temperature is a first temperature than when the operating temperature is a second temperature, the first temperature being higher than the second temperature.

16. The method according to claim 14, further comprising:
charging and discharging a capacitor electrically connected between the sense node and the second node.

17. The method according to claim 14, further comprising:
latching a voltage level sensed at the sense node.

18. The method according to claim 14, wherein the sense operation executes a positive sensing method.

19. The method according to claim 14, wherein the sense operation executes a negative sensing method.
